(19) United States
(12) Patent Application Publication
(10) Pub. No.: US 2017/0104446 A1
(43) Pub. Date: Apr. 13, 2017

(54) SOLAR BATTERY MODULE

(71) Applicants: TOYOTA JIDOSHA KABUSHIKI KAISHA, Toyota-shi (JP); KABUSHIKI KAISHA TOYOTA JIDOSHOKKI, Kariya-shi (JP)

(72) Inventors: Motoya SAKABE, Nissin-shi (JP); Kazuyoshi Ogata, Toyota-shi (JP); Shoichi Iwamoto, Izunokuni-shi (JP); Hirotaka Inaba, Kariya-shi (JP)

(73) Assignees: TOYOTA JIDOSHA KABUSHIKI KAISHA, Toyota-shi (JP); KABUSHIKI KAISHA TOYOTA JIDOSHOKKI, Kariya-shi (JP)

(21) Appl. No.: 15/285,089

(22) Filed: Oct. 4, 2016

(30) Foreign Application Priority Data
Oct. 7, 2015 (JP) 2015-199662

(51) Int. Cl. H02S 40/42; H01L 31/052; H01L 31/048

(52) U.S. Cl. CPC H02S 40/425; H01L 31/0481; H01L 31/0521

(57) ABSTRACT

A solar battery module includes: a sealing layer including a solar battery cell and a sealant sealing the solar battery cell; a front side layer formed from a resin and disposed at a side of the sealing layer at which sunlight is incident; a back side layer that is disposed at an opposite side of the sealing layer from the side at which the front side layer is disposed; and a cooler that is disposed at an opposite side of the back side from the side at which the sealing layer is disposed.

### CROSS-REFERENCE TO RELATED APPLICATIONS

This application claims priority under 35 USC 119 from Japanese Patent Application No. 2015-199662, filed on Oct. 7, 2015, the disclosure of which is incorporated herein by reference in its entirety.

### TECHNICAL FIELD

Exemplary embodiments relate to a solar battery module.

### RELATED ART

In vehicles in which electrical energy is used, such as hybrid vehicles or electric vehicles, it has been attempted to mount a solar battery module on a vehicle body, as a source for supplying electrical energy.

A solar battery module has a structure in which a sealing layer including solar battery cells sealed by a sealant is disposed between a front side layer and a back side layer. In consideration of light transmissivity to the solar battery cells, a transparent member is employed as the front side layer. Glass sheets are mainly employed as the transparent member.

Since solar battery modules in which glass sheets are used are heavy, solar battery modules including a front side layer in which resins are used instead of glass sheets have been investigated for the purpose of reducing the weight of solar battery modules (for example, Japanese Patent Application Laid-Open (JP-A) Nos. 2012-33573, 2013-168518, and 2012-216809).

### SUMMARY

When a shadow appears on a portion of a side of a solar battery module at a side at which sunlight is incident due to, for example, dirt, an extraneous material or the like attaching to the surface of a solar battery module at a side at which sunlight is incident, a problem referred to as “hot spot phenomenon” may arise in which the portion where the shadow acts as a resistor to locally generate heat.

Resins have inferior heat resistance to that of glass sheets. Therefore, when the front side layer of a solar battery module is formed from a resin, heat generated due to hot spot phenomenon may cause deterioration, such as deformation or damage, of the resinous front side layer.

Polycarbonate is one of resins used as a substitute for glass sheets. However, since polycarbonates have a significant heat insulating effect, heat generated due to hot spot phenomenon tends to be confined inside a solar battery module when the front side layer of the solar battery module is made with polycarbonates. Therefore, portions having high temperatures tend to locally arise within solar battery modules.

A general measure to avoid hot spot phenomenon is installation of bypass diodes in solar battery modules. However, there are restrictions on the placement of bypass diodes, in some cases. Therefore, there is demand for countermeasures against hot spot phenomenon other than installing bypass diodes.

In an embodiment, a solar battery module is provided that is capable of suppressing deterioration of a front side layer by heat generated due to hot spot phenomenon, even when the front side layer is formed from a resin.

A solar battery module according to a first aspect includes: a sealing layer including a solar battery cell and a sealant sealing the solar battery cell; a front side layer formed from a resin and disposed at a side of the sealing layer at which sunlight is incident; a back side layer that is disposed at an opposite side of the sealing layer from the side at which the front side layer is disposed; and a cooler that is disposed at an opposite side of the back side layer from the side at which the sealing layer is disposed.

According to the configuration above, a cooler (a heat dissipater) is disposed at the opposite side of the back side layer in the solar battery module from the side on which the sealing layer is disposed. Due to inclusion of the above configuration, even if heat is locally generated in the solar battery module by hot spot phenomenon, cooling by the cooler enables prevention of deterioration, such as deformation or damage, of the front side layer formed from a resin.

Moreover, since the cooler is disposed at the opposite side of the back side layer in the solar battery module from the side on which the sealing layer is disposed, the cooler does not obstruct incidence of sunlight and enables avoidance of a reduction of the amount of light received by the solar battery module.

A solar battery module according to a second aspect includes the first aspect, wherein the cooler includes plural fins that project out in a direction away from the back side layer along a thickness direction of the back side layer.

According to the above configuration, plural fins are disposed at the opposite side of the back side layer in the solar battery module from the side on which the sealing layer is disposed, the plural fins projecting out in the direction away from the back side layer along the thickness direction of the back side layer, namely, the thickness direction of the solar battery module. Due to inclusion of the above configuration, the rigidity of the solar battery module can be increased with respect to the load in the thickness direction of the solar battery module.

In an embodiment, a solar battery module that is capable of suppressing deterioration of a front side layer by heat generated due to hot spot phenomenon is provided, even when the front side layer is formed from a resin.

### BRIEF DESCRIPTION OF THE DRAWINGS

FIG. 1 is a cross-sectional view of a solar battery module according to a first embodiment.

FIG. 2 is a plan view of a solar battery module according to the first embodiment, as viewed from the opposite side of a sealing layer from the side at which sunlight is incident.

FIG. 3 is a plan view of a solar battery module according to a modified example of the first embodiment, as viewed from the opposite side of a sealing layer from the side at which sunlight is incident.

FIG. 4 is a cross-sectional view of a solar battery module according to a second embodiment.

FIG. 5 is a cross-sectional view of a solar battery module according to a third embodiment.

FIG. 6 is a cross-sectional view of a solar battery module according to a fourth embodiment.

FIG. 7 is a plan view of a solar battery module according to the fourth embodiment, as viewed from the opposite side of the sealing layer from the side at which sunlight is incident.

FIG. 8 is a plan view of a solar battery module according to a modified example of the fourth embodiment, as viewed from the opposite side of a sealing layer from the side at which sunlight is incident.

### DETAILED DESCRIPTION

Hereinafter, an embodiment of the solar battery module according to the present disclosure will be explained with reference to the drawings. The sizes of members in each of the drawings are merely conceptual, and the relative relationships regarding the sizes of the members are not limited thereto. Moreover, members that have substantially identical functionality are allocated the same reference numerals throughout all of the drawings, and redundant explanation is sometimes omitted.

### First Embodiment

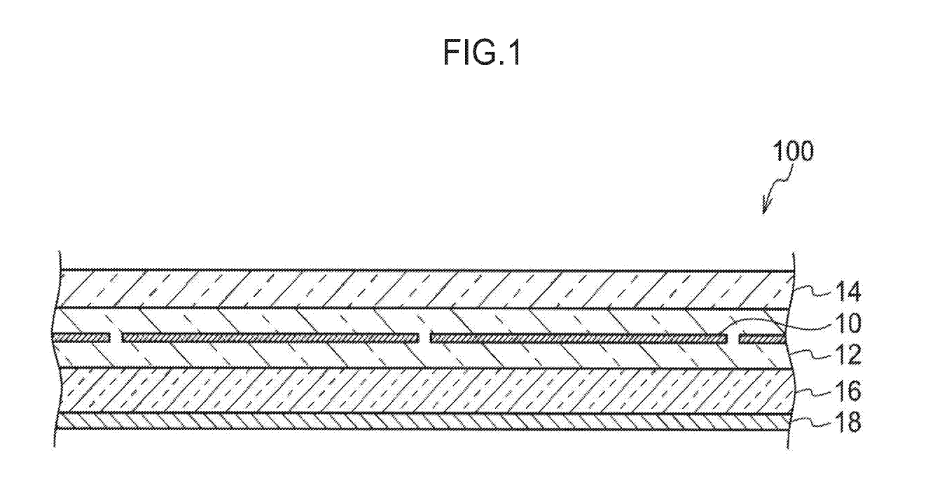

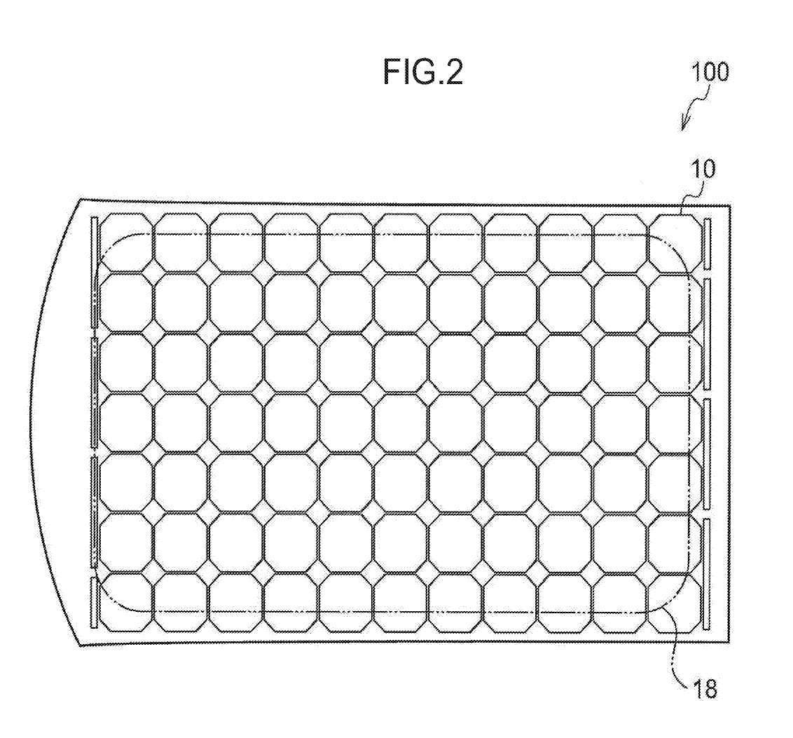

FIG. 1 is a cross-sectional view of a solar battery module according to a first embodiment. FIG. 2 is a plan view of the solar battery module according to the first embodiment, as viewed from the opposite side of a sealing layer from the side at which sunlight is incident.

As illustrated in FIG. 1, a solar battery module 100 includes: a sealing layer 12 including solar battery cells 10 and a sealant that seals the solar battery cells 10; a front side layer 14 formed from a resin and disposed at a side of the sealing layer 12 at which sunlight is incident; a back side layer 16 that is disposed at the opposite side of the sealing layer 12 from the side at which the front side layer 14 is disposed; and a metal sheet 18 serving as a cooler and disposed at the opposite side of the back side layer 16 from the side at which the sealing layer 12 is disposed.

Since the solar battery module 100 includes the metal sheet 18, heat locally generated in the solar battery module 100 due to hot spot phenomenon can be rapidly diffused along, for example, in-plane directions of the metal sheet 18. Therefore, it is possible to lower the maximum temperature reached in the solar battery module 100 due to locally generated heat, and to suppress deterioration such as deformation or damage of the front side layer 14 formed from a resin.

Moreover, since the solar battery module 100 includes the metal sheet 18, the rigidity of the solar battery module 100 is improved. Therefore, it is made possible to decrease, for example, the thickness of other members, and to decrease the weight of the solar battery module 100.

As illustrated in FIG. 2, in the solar battery module 100, plural solar battery cells 10 are arrayed, in a state in which the solar battery cells 10 are electrically connected through connecting members, which are not illustrated in the drawings. Although 77 sheets of solar battery cell 10 are arrayed in FIG. 2, the number of solar battery cells disposed in the solar battery module 100 is not limited to this example provided in the present embodiment, but may be appropriately selected as needed.

The solar battery cells 10 are not particularly limited, but conventionally known solar battery cells may be employed therefor.

Specific examples of the solar battery cells 10 include: silicon types (such as a single crystalline silicon type, a polycrystalline silicon type, and an amorphous silicon type); compound semiconductor types (such as an InGaAs type, a GaAs type, a CIGS type, and a CZTS type); dye sensitized types; and organic thin film types. Freely selected solar battery cells may be employed. Among these, silicon type solar battery cells are preferable.

The connecting members that connect the solar battery cells 10 are not particularly limited, and conventionally known connecting members may be employed therefor.

Specific examples of the connecting members include a ribbon made from solder coated copper and a metal film formed by sputtering or vapor deposition. Freely selected connecting materials may be employed therefor.

The solar battery cells 10 are sealed by a sealant. The sealing layer 12 is formed by sealing the solar battery cells 10 with the sealant.

The sealant that seals the solar battery cells 10 is not particularly limited as long as it is capable of transmitting sunlight, and conventionally known sealants may be employed therefor.

Specific examples of the material for the sealant include an ethylene-vinyl acetate (EVA) copolymer resin, a polyvinyl butyral (PVB) resin, and a silicone resin. Freely selected materials may be used therefor. Among these, EVA copolymer resins are preferable.

As needed, the sealant may include a silane coupling agent as an adhesion promoting agent. Moreover, the sealant may include an ultraviolet adsorbing agent, an antioxidant, a discoloration preventing agent, or the like.

The thickness of the sealing layer 12 may be appropriately set in consideration of, for example, the thickness of the solar battery cells 10 and the kind of the sealant. In the present embodiment, the thickness of the sealing layer 12 is preferably from 1 μm to 1 mm, more preferably from 2 μm to 500 μm, and still more preferably from 5 μm to 200 μm.

The solar battery module 100 includes the front side layer 14. The front side layer 14 is disposed at a side of the sealing layer 12 at which sunlight is incident (i.e., the light receiving face side of the solar battery cells 10), and is formed from a resin.

The resin that forms the front side layer 14 is not particularly limited as long as it is capable of transmitting sunlight, and conventionally known resins may be employed therefor.

Examples of resins usable for forming the front side layer 14 include a polycarbonate (PC) resin, a polymethylmethacrylate (PMMA) resin, a polyethylene (PE) resin, a polypropylene (PP) resin, a polystyrene (PS) resin, an acrylonitrile-butadiene-styrene (ABS) copolymer resin, an acrylonitrile-styrene (AS) copolymer resin, a polyethylene terephthalate (PET) resin, a polyethylene naphthalate (PEN) resin, a polyvinyl chloride (PVC) resin, a polyvinylidene chloride (PVDC) resin, and a silicone resin. The above resins may be employed singly or in a combination of two or more thereof.

Among these, polycarbonate (PC) resins are preferable.

Various additives may be blended with the resin that forms the front side layer 14. Examples of additives include: inorganic fibers such as glass or alumina; an organic fiber such as aramid, a polyether ether ketone, and cellulose; inorganic fillers such as silica, clay, alumina, aluminum hydroxide, and magnesium hydroxide; an ultraviolet adsorbing agent; an infrared adsorbing agent; and an antistatic agent.

The thickness of the front side layer 14 may be appropriately set in consideration of, for example, the mechanical strength of the solar battery module 100. In the present embodiment, the thickness of the front side layer 14 is preferably from 0.1 mm to 5 mm, more preferably from 0.5 mm to 3 mm, and still more preferably from 1 mm to 2 mm.

The thickness of the front side layer 14 is preferably greater than the thickness of the back side layer 16.

As needed, a protective layer may be disposed at the opposite side of the front side layer 14 from the side at which the sealing layer 12 is disposed, for the purpose of providing, for example, weather resistance and/or abrasion resistance.

The solar battery module 100 includes the back side layer 16. The back side layer 16 is disposed at the opposite side of the sealing layer 12 from the side at which the front side layer 14 is disposed.

The material that forms the back side layer 16 is not particularly limited, but the back side layer 16 is preferably formed from a resin from the viewpoint of reducing the weight of the solar battery module 100.

Conventionally known resins may be employed as the resin that forms the back side layer 16.

Examples of resins usable for forming the back side layer 16 include a polycarbonate (PC) resin, a polymethyl methacrylate (PMMA) resin, a polyethylene (PE) resin, a polypropylene (PP) resin, a polystyrene (PS) resin, an acrylonitrile-butadiene-styrene (ABS) copolymer resin, an acrylonitrile-styrene (AS) copolymer resin, a polyethylene terephthalate (PET) resin, a polyethylene naphthalate (PEN) resin, a polyvinyl chloride (PVC) resin, a polyvinylidene chloride (PVDC) resin, a polysiloxane resin, a polyimide resin, and a polyamide resin. The above resins may be used singly, or in a combination of two or more thereof.

As needed, a thermally conductive filler may be included in the resin that forms the back side layer 16, for the purpose of improving the thermal conductivity of the back side layer. Conventionally known fillers may be employed as the thermally conductive filler.

Examples of the thermally conductive filler include aluminum oxide (alumina), a hydrate of aluminum oxide, magnesium oxide, boron nitride, aluminum nitride, silicon nitride, a talc, a mica, aluminum hydroxide, and barium sulfate. The thermally conductive filler may be employed singly or in a combination of two or more thereof.

Each of the above-described various additives that may be used with the resin for forming the front side layer 14 may be further included in the back side layer 16.

The thickness of the back side layer 16 may be appropriately set in consideration of, for example, the mechanical strength of the solar battery module 100. In the present embodiment, the thickness of the back side layer 16 is preferably from 0.1 mm to 5 mm, more preferably from 0.5 mm to 3 mm, and still more preferably from 1 mm to 2 mm.

Since the front side layer 14 formed from a resin and the solar battery cell 10 have different linear expansion coefficients from each other, warping (buckling) of the solar battery module 100 may occur. In order to suppress buckling, it is preferable to dispose a material that counteracts warping of the solar battery module 100 at the opposite side of the solar battery module 100 from the side at which sunlight is incident. Therefore, it is preferable that the resin that forms the front side layer 14 and the resin that forms the back side layer 16, between which the sealing layer 12 is sandwiched, are the same resin.

The solar battery module 100 includes the metal sheet 18 serving as a cooler. The metal sheet 18 is disposed at the opposite side of the back side layer 16 from the side at which the sealing layer 12 is disposed.

Examples of usable metals for forming the metal sheet 18 include aluminum, an aluminum alloy, copper, a copper alloy, iron, and an iron alloy. The above metals may be used singly or in a combination of two or more thereof. Among these, aluminum or an aluminum alloy is preferable.

The thickness of the metal sheet 18 may be appropriately set in consideration of for example, the weight and the mechanical strength of the solar battery module 100. In the present embodiment, the thickness of the metal sheet 18 is preferably from 0.1 mm to 5 mm, more preferably from 0.3 mm to 3 mm, and still more preferably from 0.5 mm to 2 mm.

The shape of the metal sheet 18 when viewed along the thickness direction of the solar battery module 100 is not particularly limited. For example, as illustrated by the double dotted dashed line in FIG. 2, the metal sheet 18 may be disposed so as to cover substantially the whole of the surface of region in which the solar battery cells 10 are disposed, such that the individual solar battery cells 10 are covered. Disposing the metal sheet 18 so as to cover substantially the whole of the surface of the region in which the solar battery cells 10 are disposed enables cooling to be efficiently performed when heat has been locally generated in the solar battery module 100 due to hot spot phenomenon.

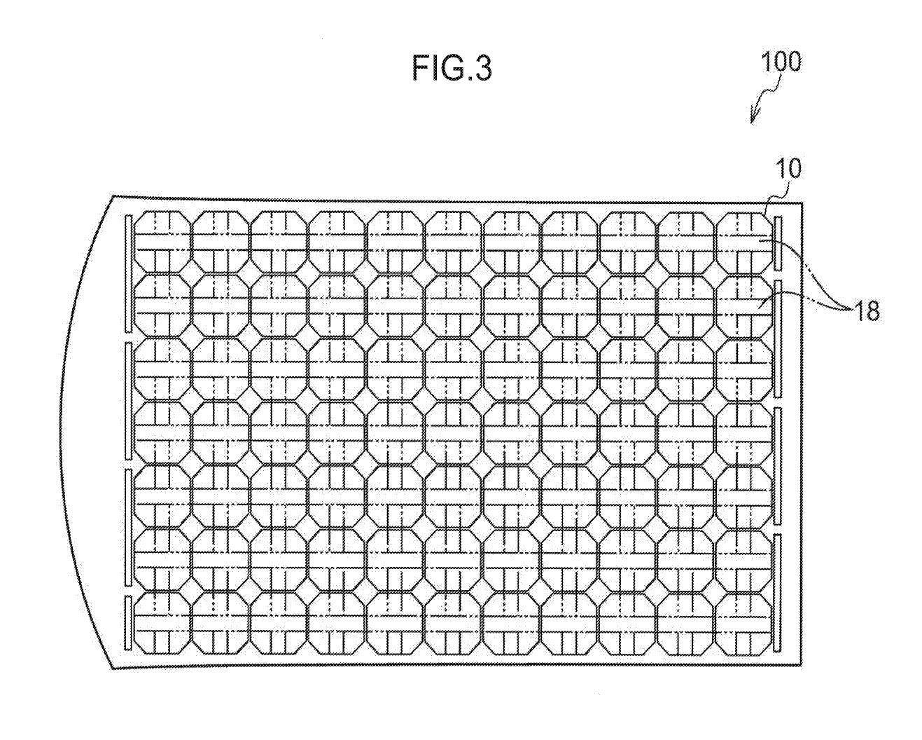

FIG. 3 is a plan view of a solar battery module according to a modified example of the first embodiment, as viewed from the opposite side of the sealing layer from the side at which sunlight is incident.

As illustrated by the double dotted dashed line in FIG. 3, rectangular metal sheets 18 may be disposed in a lattice arrangement so as to cover a portion of each of the solar battery cells 10. Disposing the rectangular metal sheets 18 in a lattice arrangement enables the weight of the cooler formed of the metal sheets 18 to be decreased.

As needed, bypass diodes may be installed in the solar battery module 100. However, there are sometimes limitations to the placement of bypass diodes in the solar battery module 100. The solar battery module 100 including the metal sheets 18 serving as the cooler enables heat locally generated due to hot spot phenomenon to be rapidly diffused. Therefore, it is made possible to lower the maximum temperature in the solar battery module 100 reached due to locally generated heat, and to decrease the number of bypass diodes disposed in the solar battery module 100.

The method used for manufacturing the solar battery module 100 is not particularly limited, and conventionally known methods may be employed therefor.

The solar battery module 100 may be manufactured by, for example, superimposing a sheet of a resin for forming the front side layer 14, a sheet-shaped sealant, the solar battery cells 10, a sheet-shaped sealant, a sheet of a resin for forming the back side layer 16, and a metal sheet serving as a cooler, in this order, and hot-pressing the resultant stack body using a vacuum laminator so as to adhere each member together.

Moreover, the solar battery module 100 may also be manufactured by superimposing a sheet of a resin for forming the front side layer 14, a sheet-shaped sealant, the solar battery cells 10, a sheet-shaped sealant, and a sheet of a resin for forming the back side layer 16, in this order, and hot-pressing the resultant stack body using a vacuum laminator so as to adhere together the members other than the metal sheet 18 to modularize the members, followed by adhering the metal sheet to the back side layer 16 side of the module using an adhesive or the like.

The conditions for hot-pressing (for example, vacuum conditions, pressure conditions, heating temperature, and retention time in the hot press) may be appropriately set in accordance with, for example, the properties of the materials employed.

When the solar battery module 100 is mounted on a vehicle that uses electrical energy, such as a hybrid vehicle or an electric vehicle, the solar battery module 100 is preferably attached to an outer panel of a vehicle body, for example, the roof or the hood. The method used for attaching the solar battery module 100 is not particularly limited, and conventionally known method may be employed.

When the solar battery module 100 is attached to an outer panel of a vehicle body, the metal sheet 18 is preferably attached so as to contact at least a portion of the outer panel. When the metal sheet 18 contacts at least a portion of the outer panel, heat locally generated in the solar battery module 100 due to hot spot phenomenon is efficiently diffused toward the vehicle body through the metal sheet 18. Therefore, cooling efficiency is improved.

### Second Embodiment

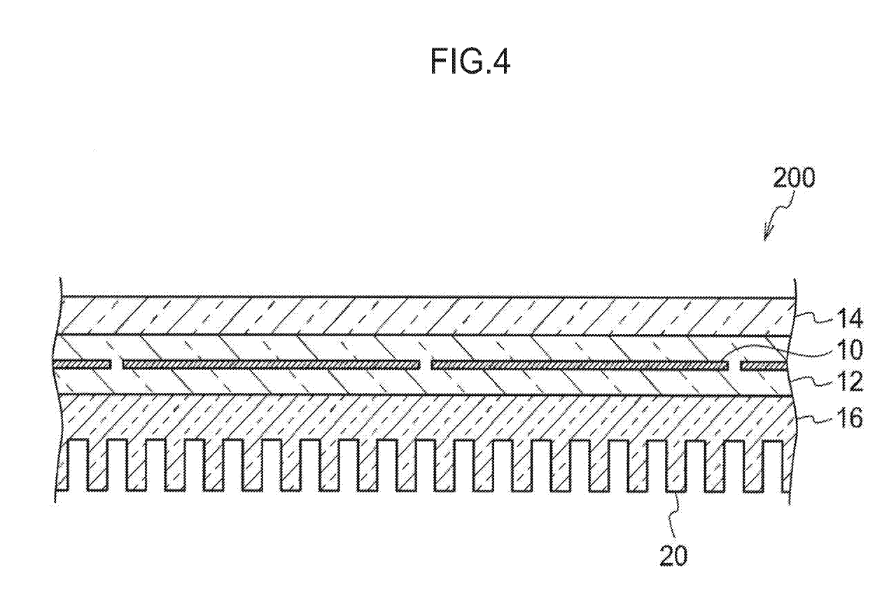

FIG. 4 is a cross-sectional view of a solar battery module according to a second embodiment.

As illustrated in FIG. 4, a solar battery module 200 has the same configuration as that of the solar battery module 100 illustrated in FIG. 1, except that plural fins 20 projecting out in a direction away from the back side layer 16 along the thickness direction of the back side layer 16 is employed as a cooler instead of the metal sheet 18. In the present embodiment, the fins 20 are integrally formed with the back side layer 16.

The solar battery module 200 includes plural fins 20 projecting out in the direction away from the back side layer 16 along the thickness direction of the back side layer 16. Therefore, it is possible to rapidly dissipate heat through the fins 20 when heat has been locally generated in the solar battery module 200 due to hot spot phenomenon. Therefore, it is possible to lower the maximum temperature reached in the solar battery module 200 due to locally generated heat, and to suppress deterioration, such as, deformation or damage, of the front side layer 14 formed from a resin.

Moreover, since the solar battery module 200 includes plural fins 20 projecting out in the direction away from the back side layer 16 along the thickness direction of the back side layer 16 (i.e., the thickness direction of the solar battery module 200), the rigidity of the solar battery module 200 with respect to the load along the thickness direction of the solar battery module 200 can be improved.

Moreover, improvement of the rigidity of the solar battery module 200 enables, for example, the thickness of other members in the solar battery module 200 to be decreased, and enables the weight of the solar battery module 200 to be decreased.

Although explanation has been given in the present embodiment regarding a configuration in which the fins 20 are integrally formed with the back side layer 16, a heat dissipating plate including a plate-shaped base and fins projecting out in a direction away from the base along the thickness direction of the base may be employed as the cooler. The heat dissipating plate is preferably made of a metal having excellent thermal conductivity, such as aluminum or copper.

The heat dissipating plate is disposed such that the base of the heat dissipating plate contacts the back side layer 16.

Moreover, the heat dissipating area of the back side layer 16 may be increased by forming a bead or a bump on the back side layer 16 instead of the fins.

The term “bead” means a ridge portion formed on the back side layer 16. The term “bump” means a projection portion projecting out in the direction away from the back side layer 16 along the thickness direction of the back side layer 16, and having, for example, a column shape or a semi-spherical shape.

The method used for attaching the solar battery module 200 to an outer panel of a vehicle body is not particularly limited, and a conventionally known method may be employed therefor. For example, the solar battery module 200 may be attached to the outer panel by joining at least a portion of the fins, beads, or bumps to the outer panel. Alternatively, the outer panel and a side of the solar battery module 200 at which the cooler (the fins, the beads, or the bumps) is disposed may be made to face each other, and the solar battery module 200 may be attached to the outer panel with a spacer disposed between the outer panel and the side of the solar battery module 200.

A space is created between the outer panel and the solar battery module 200 by disposing the spacer between the outer panel and the solar battery module 200. Allowing air to pass through this space enables the cooling efficiency of the solar battery module 200 to be further improved.

The flow of air passing through the space created between the outer panel and the solar battery module 200 may be forcefully generated by a fan or the like, or the flow of air may be generated by utilizing the flow of air generated by the vehicle travelling.

### Third Embodiment

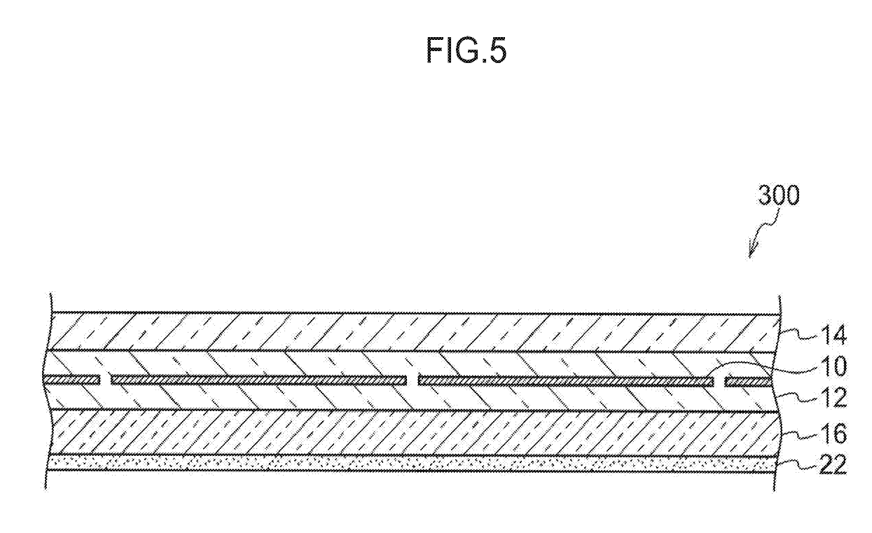

FIG. 5 is a cross-sectional view of a solar battery module according to a third embodiment.

As illustrated in FIG. 5, a solar battery module 300 has the same configuration as that of the solar battery module 100 illustrated in FIG. 1, except that a heat dissipating coating layer 22 is employed as a cooler instead of the metal sheet 18.

The heat dissipating coating layer 22 may be formed using, for example, a blackbody coating material capable of forming a coating film that has emissivity similar to that of a blackbody.

Since the solar battery module 300 includes the heat dissipating coating layer 22, heat can be rapidly diffused, for example, along in-plane directions of the heat dissipating coating layer 22 when heat has been locally generated in the solar battery module 300 due to hot spot phenomenon. Therefore, it is possible to lower the maximum temperature reached due to locally generated heat, and to suppress deterioration, such as, deformation or damage, of the front side layer 14 formed from a resin.

The composition of the blackbody coating material is not particularly limited, and a conventionally known composition may be applied.

Blackbody coating materials generally contain a thermally conductive pigment and a binding resin. As needed, the blackbody coating material may contain a solvent.

Examples of thermally conductive pigments that can be contained in the blackbody coating material include: carbon blacks such as furnace black, channel black, thermal black, or acetylene black; graphite; SiZrO₄; Mn₂O₃; and Fe₂O₃. The above-described pigments may be employed singly or in a combination of two or more thereof.

Examples of binding resins that can be contained in the blackbody coating material include a phenol resin, a melamine resin, a xylene resin, a diallylphthalate resin, a glyptal resin, an epoxy resin, an alkylbenzene resin, a polyimide resin, a silicate resin, an acrylic acid resin, polyvinyl alcohol, and a polyester resin. Various resins may be employed as long as they have excellent heat resistance and flowability, and do not impede the dispersibility of pigments such as a carbon black. The above-described binding resins may be employed singly or in a combination of two or more thereof.

As the solvent that may be contained in the blackbody coating material as needed, a polar solvent having low surface tension and low viscosity, such as water, ethanol, N-methyl-2-pyrrolidone, 2-pyrrolidone, N,N-dimethyl formamide, dimethyl acetamide, dimethyl sulfoxide, or hexamethyl phosphamide, is preferable. Moreover, a mixed solvent of water and, for example, ethanol, ethylene glycol, diethylene glycol, ethylene glycol butylether, or diethylene glycol butylether, may be also preferably employed.

The thickness of the heat dissipating coating layer 22 is not particularly limited, and may be appropriately set in consideration of, for example, the heat dissipating properties of the blackbody coating material that forms the heat dissipating coating layer 22. The thickness of the heat dissipating coating layer 22 is, for example, preferably from 1 μm to 300 μm, more preferably from 2 μm to 200 μm, and still more preferably from 3 μm to 100 μm.

When the heat dissipating coating layer 22 is colored in black or the like, coloring of the back side layer 16 which is otherwise performed as necessary becomes unnecessary, thus simplifying the manufacturing process of the solar battery module 300.

In the present embodiment, although explanation has been given regarding a configuration in which the heat dissipating coating layer 22 is disposed at a side of the back side layer 16, the present embodiment is not limited to the above-described configuration. For example, the heat dissipating coating layer 22 may be disposed at a side of the metal sheet 18 included in the solar battery module 100 according to the first embodiment. Moreover, the heat dissipating coating layer 22 may be disposed at a side of the back side layer 16 having the fins 20 included in the solar battery module 200 according to the second embodiment.

The method used for attaching the solar battery module 300 to an outer panel of a vehicle body is not particularly limited, and a conventionally known method may be employed. For example, the outer panel and a side of the solar battery module 300 at which the cooler (the heating dissipating coating layer 22) is disposed may be made to face each other, and the solar battery module 300 may be attached to the outer panel with a spacer disposed between the outer panel and the side of the solar battery module 300. Alternatively, the solar battery module 300 may be attached to the outer panel such that the heat dissipating coating layer 22 contacts at least a portion of the outer panel.

### Fourth Embodiment

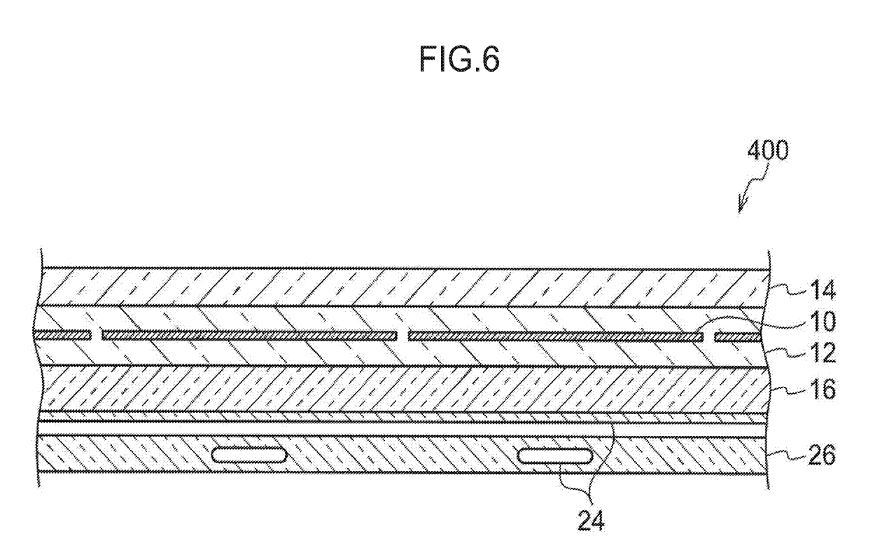

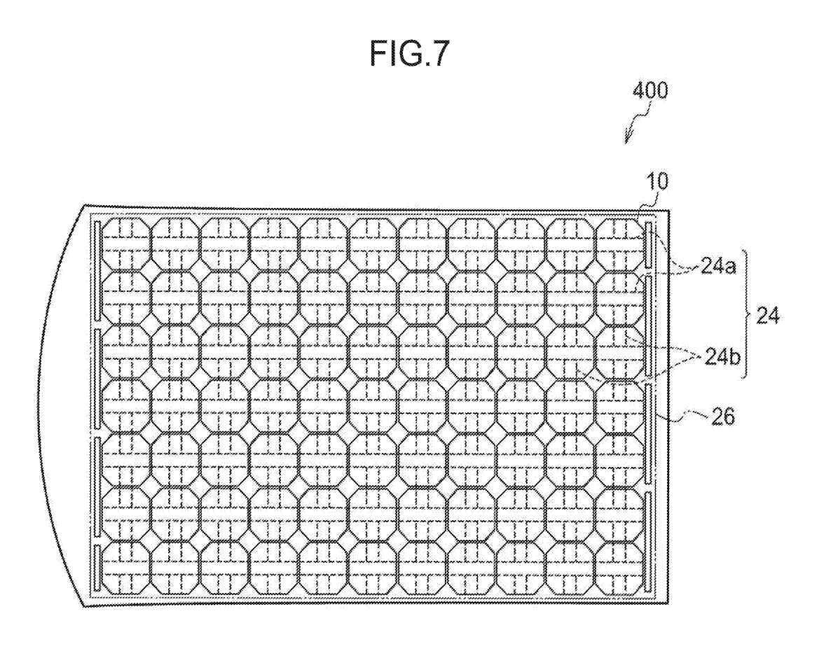

FIG. 6 is a cross-sectional view of a solar battery module according to a fourth embodiment. Moreover, FIG. 7 is a plan view of the solar battery module according to the fourth embodiment, as viewed from the opposite side of the sealing layer from the side at which sunlight is incident.

As illustrated in FIG. 6, a solar battery module 400 has the same configuration as that of the solar battery module 100 illustrated in FIG. 1, except that a cooling member 26 having coolant water pathways 24 inside the cooling member 26 is used as a cooler instead of the metal sheet 18.

The solar battery module 400 includes the cooling member 26. Due to this configuration, heat can be rapidly removed by the cooling member 26 when heat has been locally generated in the solar battery module 400 due to hot spot phenomenon. Therefore, it is possible to lower the maximum temperature reached due to locally generated heat, and to suppress deterioration, such as deformation or damage, of the front side layer 14 formed from a resin.

It is known that the power generation efficiency of the solar battery cells is influenced by temperature, and the power generation efficiency decreases by approximately 0.2% for every 1° C. increase in temperature. The configuration of the solar battery module 400 enables the temperature of the solar battery cells 10 to be lowered by the cooling member 26. Therefore, this configuration makes it possible to improve the power generation efficiency of the solar battery cells 10 by cooling the solar battery cells 10, as a result of which the output of the solar battery module 400 increases.

The shape or the like of the coolant water pathways 24 disposed inside the cooling member 26 is not particularly limited. FIG. 7 is a plan view of a solar battery module according to the fourth embodiment, as viewed from the opposite side of the sealing layer from the side at which sunlight is incident. The coolant water pathways 24 disposed in the cooling member 26 are illustrated by dashed lines in FIG. 7.

In FIG. 6 and FIG. 7, the coolant water pathways 24 are configured by coolant water pathways 24a disposed along the longitudinal direction of the solar battery module 400, and coolant water pathways 24b disposed along the transverse direction of the solar battery module 400. The coolant water pathways 24a and the coolant water pathways 24b are disposed in a lattice arrangement so as to intersect with each other at or around the center regions of the respective solar battery cells 10. Each of the coolant water pathways 24 is connected to a coolant water inlet and coolant a water outlet, which are not illustrated in the drawings, such that a cooling medium such as coolant water can pass through the coolant water pathways 24.

The material that forms the cooling member 26 is not particularly limited, and a conventionally known material may be employed.

Examples of materials usable for forming the cooling member 26 include: metallic materials such as aluminum, an aluminum alloy, copper, a copper alloy, iron, and an iron alloy; and resin materials such as a polycarbonate (PC) resin, a polymethyl methacrylate (PMMA) resin, a polyethylene (PE) resin, a polypropylene (PP) resin, a polystyrene (PS) resin, an acrylonitrile-butadiene-styrene (ABS) copolymer resin, an acrylonitrile-styrene (AS) copolymer resin, a polyethylene terephthalate (PET) resin, a polyethylene naphthalate (PEN) resin, a polyvinyl chloride (PVC) resin, a polyvinylidene chloride (PVDC) resin, a polysiloxane resin, a polyimide resin, and a polyamide resin. The above materials may be used singly or in a combination of two or more thereof.

When the cooling member 26 is formed from a resin material, the back side layer 16 and the cooling member 26 may be formed integrally with each other.

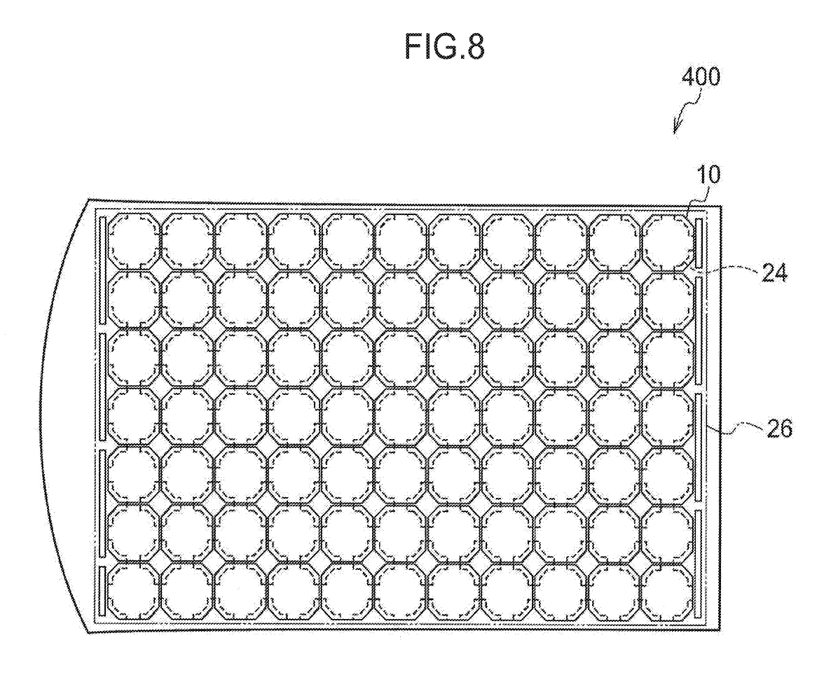

FIG. 8 is a plan view of a solar battery module according to a modified example of the fourth embodiment, as viewed from the opposite side of the sealing layer from the side at which sunlight is incident. In FIG. 8, there are a locations at which the coolant water pathways 24 illustrated by dashed lines are broadened, mirroring the locations at which the solar battery cells 10 are provided. This configuration further increases the efficiency of cooling of the solar battery cells 10.

The method used for attaching the solar battery module 400 to an outer panel of a vehicle body is not particularly limited, and a conventionally known method may be employed therefor. For example, preferably, the outer panel and a side of the solar battery module 400 at which the cooling member 26 is provided are made to face each other, and the solar battery module 400 is attached such that the cooling member 26 contacts at least a portion of the outer panel.

In the present embodiment, for example, the coolant water of an engine of a vehicle may also be used as the coolant water passing through the coolant water pathways 24.

What is claimed is:

1. A solar battery module, comprising:
a sealing layer comprising a solar battery cell and a sealant, the sealant sealing the solar battery cell;
a front side layer formed from a resin and disposed at a side of the sealing layer at which sunlight is incident;
a back side layer that is disposed at an opposite side of the sealing layer from the side at which the front side layer is disposed; and
a cooler that is disposed at an opposite side of the back side layer from the side at which the sealing layer is disposed.

2. The solar battery module according to claim 1, wherein the cooler comprises a plurality of fins that project out in a direction away from the back side layer along a thickness direction of the back side layer.

3. The solar battery module according to claim 1, wherein the cooler comprises a metal sheet.

4. The solar battery module according to claim 3, wherein the metal sheet comprises at least one selected from the group consisting of aluminum, an aluminum alloy, copper, a copper alloy, iron, and an iron alloy.

5. The solar battery module according to claim 3, wherein a thickness of the metal sheet is from 0.1 mm to 5 mm.

6. The solar battery module according to claim 3, wherein the sealing layer comprises a plurality of solar battery cells, and the metal sheet is disposed so as to cover substantially an entire surface of a region in which the solar battery cells are disposed.

7. The solar battery module according to claim 3, wherein the sealing layer comprises a plurality of solar battery cells, the metal sheet is rectangular, and the metal sheet is disposed in a lattice arrangement so as to cover a portion of each of the solar battery cells.

8. The solar battery module according to claim 1, wherein the cooler comprises a heat dissipating plate, the heat dissipating plate comprising a plate-shaped base and fins projecting out in a direction away from the plate-shaped base along a thickness direction of the plate-shaped base.

9. The solar battery module according to claim 8, wherein the heat dissipating plate is formed from a metal.

10. The solar battery module according to claim 1, wherein the cooler comprises a heat dissipating coating layer.

11. The solar battery module according to claim 10, wherein the heat dissipating coating layer is formed from a blackbody coating material.

12. The solar battery module according to claim 11, wherein the blackbody coating material comprises a thermally conductive pigment and a binding resin.

13. The solar battery module according to claim 12, wherein the thermally conductive pigment comprises at least one selected from the group consisting of carbon black, graphite, SiZrO₄, Mn₂O₃, and Fe₂O₃.

14. The solar battery module according to claim 12, wherein the binding resin comprises at least one selected from the group consisting of a phenol resin, a melamine resin, a xylene resin, a diallylphthalate resin, a glyptal resin, an epoxy resin, an alkylbenzene resin, a polyimide resin, a silicate resin, an acrylic acid resin, polyvinyl alcohol, and a polyester resin.

15. The solar battery module according to claim 10, wherein a thickness of the heat dissipating coating layer is from 1 μm to 300 μm.

16. The solar battery module according to claim 1, wherein the cooler comprises a cooling member in which coolant water pathways are disposed inside the cooling member.

17. The solar battery module according to claim 16, wherein:
the coolant water pathways comprise a coolant water pathway (a) disposed along a longitudinal direction of the solar battery module, and a coolant water pathway (b) disposed along a transverse direction of the solar battery module;
the coolant water pathway (a) and the coolant water pathway (b) are disposed in a lattice arrangement so as to intersect with each other at, or in a vicinity of, center regions of each of the solar battery cells; and
the cooling member is configured to allow a cooling medium to pass through the coolant water pathways (a) and (b).
